(19) United States
(12) Patent Application Publication
(10) Pub. No.: US 2005/0189598 A1
(43) Pub. Date: Sep. 1, 2005

(54) Logic embedded-memory integrated circuits

(75) Inventors: Syun-Ming Jang, Hsin-Chu (TW); Horng-Huei Tseng, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/826,899

(22) Filed: Apr. 16, 2004

Related U.S. Application Data
(60) Provisional application No. 60/548,443, filed on Feb. 27, 2004.

(51) Int. Cl. H01L 21/336

(52) U.S. Cl. 257/400

(57) ABSTRACT

A semiconductor device and a method for fabricating such a device is disclosed. In one example, the semiconductor device includes a substrate, one or more logic devices formed over the substrate, and one or more memory devices formed over the substrate. The logic device may include a high dielectric constant (high-k) gate dielectric, while the memory device may include a non-high-k gate dielectric.

### BACKGROUND

The present disclosure relates to the manufacturing of semiconductor devices, and particularly to a system and method of forming logic embedded-memory integrated circuits.

An integrated circuit (IC) is formed by creating one or more devices (e.g., circuit components) on a semiconductor substrate using fabrication processes. Since semiconductor devices were first introduced several decades ago and with the advancement of fabrication processes and materials, semiconductor device sizes have continued to decrease. For example, current fabrication processes are producing devices with geometry sizes (e.g., the smallest component (or line) that may be created using the process) of less than 0.09 μm. However, the reduction of semiconductor device sizes frequently introduces new challenges to semiconductor manufacturers.

In one example, as semiconductor devices are scaled below 0.09 μm, ultra thin SiO₂ gate oxide dielectric films that form portions of the devices may exhibit undesirable current leakage. For a logic embedded memory device, logic device areas are especially prone to such current leakage.

Accordingly, it is desirable to provide improved integrated circuits that alleviate such current leakage while meeting the requirements of operating voltages for logic and memory devices.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a cross-sectional view of a partial integrated circuit that includes both memory and logic devices according to one embodiment of the present disclosure.

FIG. 2 illustrates a cross-sectional view of a partial integrated circuit that includes both memory and logic devices with different gate materials according to one embodiment of the present disclosure.

FIG. 3 illustrates a method for fabricating the circuit of FIG. 2 according to one embodiment of the present disclosure.

### DETAILED DESCRIPTION

The present disclosure relates generally to the manufacturing of semiconductor devices, and particularly to a system and method of forming logic embedded-memory integrated circuits.

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

In order to minimize current leakage while maintaining high drive current, suitable equivalent oxide thickness (EOT) may be achieved by utilizing films with higher dielectric constants (k). EOT is a thickness value designated for comparing the performance of non-silicon oxide(SiO₂) gate dielectrics with the performance of silicon dioxide (SiO₂) gate dielectrics. For example, EOT may represent the thickness of silicon dioxide (SiO₂) gate oxide required to obtain the same gate capacitance as that of an alternative dielectric layer with a different dielectric constant k. Accordingly, one method for reducing current leakage is by adopting a high-k dielectric film (i.e., a film having a dielectric constant k that is greater than that of silicon oxide) for the gate dielectric of a logic device.

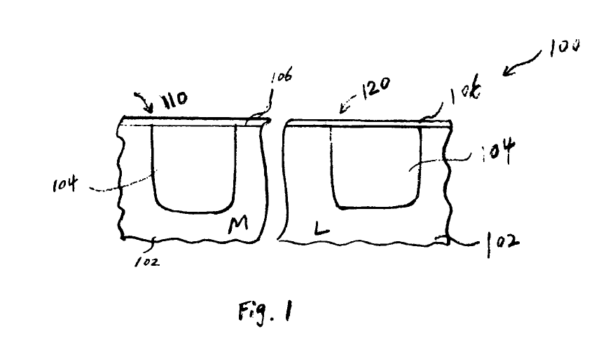

Referring now to FIG. 1, shown therein is a cross-sectional view of a partial semiconductor device 100 that includes both memory and logic devices. In this embodiment, the semiconductor device 100 may comprise one or more memory regions 110 and logic regions 120. The memory regions 110, which are designated “M”, may represent a dynamic random access memory (DRAM) (including but not limited to stack-type DRAM and trench-type DRAM), static random access memory (SRAM), non-volatile memory, flash memory, and/or other memory devices. The logic regions 120, which are designated “L”, may represent a metal-oxide semiconductor field-effect transistor (MOSFET) and/or other logic devices. In one example, the MOSFET may have a channel in <100> crystalline direction to further enhance device and circuit performance. In another example, at least one of the logic devices may have an electrically conductive gate electrode that includes metal, metal nitride, metal alloy, a metal compound, combinations thereof, and/or other materials.

The formation of the semiconductor device 100 may commence with a substrate 102. The substrate 102 may comprise silicon, silicon-on-insulator (SOI), silicon with defective crystalline and/or diamond or other suitable materials. The substrate 102 may be n-type doped or p-type doped, and is n-type doped in the present example for purposes of illustration. The substrate 102 may be provided with one or more isolation features (not shown). The isolation features may comprise local oxidation of silicon (LOCOS) structures and/or shallow trench isolation (STI) structures that are formed in the substrate 102 to electrically isolate device areas.

In this example, well regions 104 may be formed in the substrate 102 by ion implantation (although use of a p-type doped substrate may negate the need for a well region). For example, each of the well regions 104 may be formed by growing a sacrificial oxide layer on the substrate 102, opening a pattern for the location of the well, and then using a chained-implantation procedure. It is understood that the substrate 102 may have a p-type doped well, n-type doped well, and/or a combination thereof. While not being limited to any particular dopant type or scheme, in one embodiment, the well regions 104 may employ boron as a p-type dopant and deuterium-boron complexes for a n-type dopant. The deuterium-boron complexes may be formed by plasma treatment of boron-doped diamond layers with a deuterium plasma.

In one embodiment, the well regions 104 may be formed by a high density plasma source with a carbon-to-deuterium ratio ranging between about 0.1 percent and about 5 percent in a vacuum process ambient. Boron doping may be provided by the mixing of a boron containing gas with a carbon/hydrogen gas. The boron containing gas may include B₂H₆, B₂D₆, and/or other boron containing gases. The concentration of boron doping may depend upon the amount of boron containing gas that may be leaked or added into the process. The process ambient pressure may range between about 0.1 mTorr and about 500 Torr. The substrate 102 may be held at a temperature ranging between about 150° C. and about 1100° C. High density plasma may be produced by a microwave electron cyclotron resonance (ECR) plasma, a helicon plasma, an inductively coupled plasma, and/or other high density plasma sources. For example, the ECR plasma may utilize microwave powers ranging between about 800 Watts and about 2500 Watts.

As described above, the well regions 104 may also comprise n-type deuterium-boron complex regions of the substrate 102, which may be formed by treating the above-described boron-doped regions employing a deuterium plasma. For example, selected areas of the substrate 102 may be covered by photoresist or another type of mask, so that exposed boron-doped regions may be treated with the deuterium containing plasma. The deuterium ions may provide termination of dangling bonds, thereby transmuting the p-type boron-doped regions into n-type deuterium-boron complex regions. Alternatively, deuterium may be replaced with tritium, hydrogen and/or other hydrogen containing gases. The concentration of the n-type regions may generally be controlled by a direct current (DC) or a radio frequency (RF) bias of the substrate 102. The above-described processes may also be employed to form lightly-doped source/drain regions in the substrate 102. Of course, other conventional and/or future-developed processes may also or alternatively be employed to form the source/drain regions.

In furtherance of the example, an insulating layer 106 may be deposited or formed over the substrate 102. The insulating layer 106 may comprise a variety of different materials, including but not limited to, silicon dioxide(SiO₂), silicon nitride(SiN), silicon oxynitride(SiON), SiC, CN, and SiOC. The insulating layer 106 may be used as part of a MOS gate dielectric,. Formation of the insulating layer 106 may include thermal oxidizing silicon substrate 102 to form thermal silicon oxide then nitridizing said thermal silicon oxide in nitrogen ambient to form silicon oxynitride.

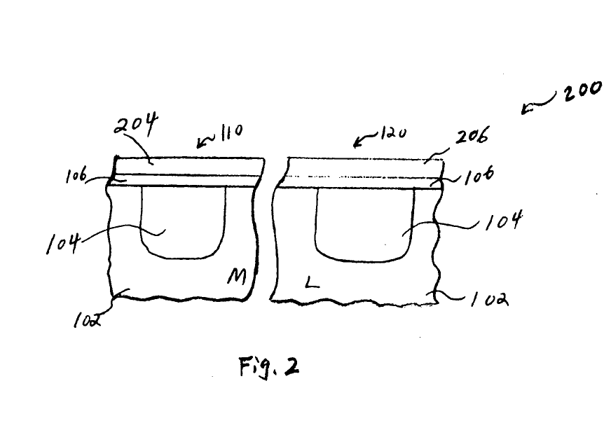

Referring now to FIG. 2, shown therein is a cross-sectional view of a partial semiconductor device 200 that includes different gate materials for memory and logic devices. In this embodiment, a gate dielectric 206 may be deposited in the logic regions L on or over the insulating layer 106 and/or the substrate 102. The gate dielectric 206 may comprise a high-k dielectric material, such as hafnium silicon(HfSiₓ), hafnium oxide(HfOx), hafnium silicon oxide(HfSiOx), hafnium silicon oxynitride(HfSixONy), hafnium silicon nitride(HfSiₓN_{y}), hafnium aluminum oxide(HfAlOₓ), aluminum oxide, titanium oxide, strontium titanium oxide, tantalum pentoxide(Ta2O5), zirconium oxide(ZrO2), zirconium silicon oxide, barium strontium titanate, lead-lanthanum-zirconim-titanate, and/or other suitable materials. The gate dielectric 206 may be formed by atomic layer deposition (ALD), sputtering, low pressure chemical vapor deposition (LPCVD), plasma enhanced chemical vapor deposition (PECVD), evaporation, and/or other methods. Generally, the k of the gate dielectric 206 may be at least 20. Also, the gate dielectric 206 may have a thickness of less than approximately 50 Angstroms. However, other k figures and thicknesses are also contemplated for the gate dielectric 206. In one example, gate dielectric materials, such as hafnium oxide, may be blanket deposited on or over the insulating layer 106 to form the gate dielectric 206. In another example, gate dielectric materials may be selectively deposited. In a third example, it may be desirable to blanket deposit some materials, such as hafnium oxide, in some fabrication processes, while selectively depositing the same materials in other processes.

In furtherance of the example, the gate dielectric 206 may be formed by ALD, which may provide good step coverage (even on large areas), and a dense and pinhole free structure. ALD may be particularly useful for the deposition of metals and metal oxides in high packing density and/or high aspect ratio applications that include relatively demanding thin film requirements. In ALD, films grow with a relatively constant growth rate, and each deposition cycle ideally produces one molecular layer of the deposited material on the substrate surface. However, in reality, the growth rate is below one molecular layer per cycle because the absorbed source chemical molecules may be bulky or the substrate temperature may affect the number of active sites (e.g., —OH groups) on the substrate surface. Metal oxide thin films produced by ALD are generally uniform and have desirable adhesion properties that allow them to become firmly bonded to the substrate surface.

In this example, the ALD of a high-k material, such as HfO₂, may be achieved by co-reacting a precursor in the presence of a gas, and then purging the precursor using the same gas. For HfO₂, ALD may utilize a precursor of Hf, such as HfCl₄, or other organometallic Hf sources having a variety of ligands attached to the Hf atom. For example, appropriate precursors may include HfCl₄ or Hf(OR)₄, wherein R is an alkyl such as CH(CH₃)₂; Hf(tmdh)₄, wherein tmdh=2,2,6,6-tetramethyl-3,5-heptanedionato; Hf(tfac)₄, wherein tfac=trifluoroacetylacetonate; or Hf(NO₃)₄. Similar precursors may be used for the ALD of other high-k materials, such as ZrO₂. Because carbon containing hafnium precursors may result in excess carbon and fluorine incorporation in the metal oxide film, HfCl₄ may be a desirable choice, as it may result in limited residual chlorine incorporation. HfCl₄ may also be a desirable metal oxide precursor, because it may be sublimated by injection and vaporization into the process reactor.

In furtherance of the example, H₂O vapor may be selected as an oxygen source for the HfO₂. In the present example, a HfO₂ deposition process may be accomplished at a temperature ranging between about 200° C. and about 400° C., or about 300° C., with a deposited film thickness ranging between about 3 Angstroms and about 75 Angstroms, or about 35 Angstroms. The ALD process may be performed in cycles with a series of HfO₂ monolayers formed during each cycle, until the desired film thickness is achieved for the gate dielectric 206. It is contemplated that other temperatures and thicknesses are also contemplated by the present disclosure.

Referring again to FIG. 2, shown therein on the left side is a cross-sectional view of partial memory device regions 110. In this embodiment, a gate dielectric 204 may be deposited over or on the insulating layer 106 and/or the substrate 102. The gate dielectric 204 may comprise silicon oxide, silicon nitride, silicon oxynitride, or other suitable non-high-k materials that provide adequate electrical device performance based upon application-specific requirements. The gate dielectric 204 may be formed by thermal oxidation of substrate 102, ALD, CVD, RTP or other processes. In one example, the gate dielectric 204 may comprises a material with k of less than 8, and its thickness may be less than about 15 Angstroms. However, other k values and thicknesses are also contemplated. It will be understood that that the formation of the gate dielectric 204 are known in the art, and will not be further described here.

Since forming logic device gate(s) and memory device gate(s) in the logic regions and memory regions 120 and 110, respectively, are known in the art, they will not be further described herein. In one example, a gate electrode (not shown) of a logic or memory device may comprise metal silicide, polysilicon, metal, metal nitride, metal alloy, metal compound, or other suitable materials. In another example, the width of the gate electrode of a logic or memory device may be less than about 2500 Angstroms. However, other widths are also contemplated. Since subsequent steps of forming a complete logic embedded-memory device are known in the art, they will not be further described herein.

It is contemplated that many variations of the above embodiments are also anticipated. In one example, instead of utilizing high-k materials for the gate dielectric of logic devices and non-high-k materials for the gate dielectric of memory devices, high-k materials may be utilized for the gate dielectric of memory devices, while non-high-k materials may be utilized for the gate dielectric of logic devices. In a second example, high-k materials may be used for the gate dielectric of selected logic devices, while non-high-k materials may be used for the gate dielectric of selected memory devices. In a third example, non-high-k materials may be used for the gate dielectric of selected logic devices, while high-k materials may be used for the gate dielectric of selected memory devices.

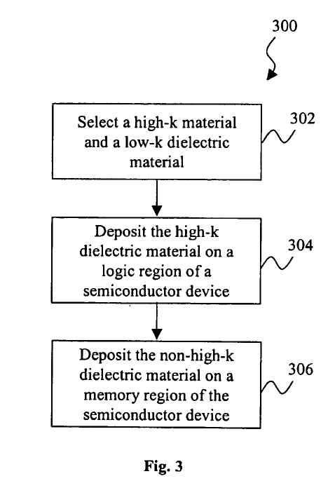

Referring now to FIG. 3, an exemplary method 300 illustrates one process by which a portion of the semiconductor device 200 of FIG. 2 may be fabricated. In step 302, a high-k dielectric and a non-high-k dielectric (relative to the high-k dielectric) may be selected. In step 304, the high-k dielectric may be deposited onto or above a logic region of the semiconductor device 200, such as the logic region 120 of FIG. 2. In step 306, the non-high-k dielectric may be deposited onto or above a memory region of the semiconductor device 200, such as the memory region 110 of FIG. 2. Accordingly, materials with different k values may be applied to different regions of the semiconductor device 200. It is understood that the method 300 represents one example, and that the method 300 may be modified. For example, various steps of the method 30 may be performed in a different order, the high-k dielectric may be applied to the memory region while the non-high-k dielectric may be applied to the logic region, and/or other changes may be made.

Although only a few exemplary embodiments of this disclosure have been described in detail above, those skilled in the art will readily appreciate that many modifications are possible in the exemplary embodiments without materially departing from the novel teachings and advantages of this disclosure. Also, features illustrated and discussed above with respect to some embodiments can be combined with features illustrated and discussed above with respect to other embodiments. Accordingly, all such modifications are intended to be included within the scope of this disclosure.

1. A semiconductor device, comprising:
a substrate;
one or more logic devices formed over the substrate, wherein at least one of the one or more logic devices comprises a high dielectric constant (high-k) gate dielectric; and
one or more memory devices formed over the substrate, wherein at least one of the one or more memory devices comprises a non-high-k gate dielectric.

2. The semiconductor device of claim 1 wherein the substrate comprises defective crystalline to accommodate logic devices with strained channel.

3. The semiconductor device of claim 1 wherein the k of the high-k gate dielectric is at least 20.

4. The semiconductor device of claim 1 wherein the k of the non-high k gate dielectric is less than 8.

5. The semiconductor device of claim 1 wherein the logic device comprises a metal-oxide semiconductor field-effect transistor (MOSFET).

6. The semiconductor device of claim 1 wherein the memory device comprises a dynamic random access memory (DRAM).

7. The semiconductor device of claim 1 wherein the memory device comprises a static random access memory (SRAM).

8. The semiconductor device of claim 1 wherein the memory device comprises a non-volatile memory.

9. The semiconductor device of claim 1 wherein the memory device comprises Electrically Programmable Memory (EPROM) or Electrically Erasable Programmable Memory (E2PROM).

10. The semiconductor device of claim 1 wherein the thickness of the high-k gate dielectric is less than about 50 Angstroms.

11. The semiconductor device of claim 1 wherein the thickness of the non-high-k gate dielectric is less than about 15 Angstroms.

12. The semiconductor device of claim 1 wherein the high-k gate dielectric comprises tantalum pentoxide.

13. The semiconductor device of claim 1 wherein the high-k gate dielectric comprises hafnium oxide.

14. The semiconductor device of claim 1 wherein the high-k gate dielectric comprises aluminum oxide.

15. The semiconductor device of claim 1 wherein the high-k gate dielectric comprises one of the following: titanium oxide, barium strontium titanate, zirconium oxide, hafnium silicon oxide, zirconium silicon oxide, hafnium aluminum oxide, zirconium aluminum oxide, and strontium titanium oxide.

16. The semiconductor device of claim 1 wherein the non-high-k gate dielectric comprises one of the following: silicon oxide, silicon nitride, and silicon oxynitride.

17. A semiconductor device, comprising:
a substrate;
a first gate dielectric over the substrate, wherein the first gate dielectric is for a logic device and comprises a high dielectric constant (high-k) material;
a second gate dielectric over the substrate, wherein the second gate dielectric is for a memory device and comprises a non-high-k material; and
and a gate electrode over the second gate dielectric.

18. The semiconductor device of claim 17 further comprising forming an insulating layer that comprises silicon nitride or silicon oxynitride under the first gate dielectric.

19. The semiconductor device of claim 17 wherein the first gate dielectric comprises hafnium oxide.

20. The semiconductor device of claim 17 wherein the first gate dielectric one of the following: tantalum pentoxide, titanium oxide, barium strontium titanate, zirconium oxide, hafnium silicon oxide, zirconium silicon oxide, hafnium aluminum oxide, zirconium aluminum oxide, and strontium titanium oxide.

21. The semiconductor device of claim 17 wherein the second gate dielectric comprises one of the following: silicon oxide, silicon nitride, and silicon oxynitride.

22. The semiconductor device of claim 17 wherein the substrate comprises silicon-on-insulator.

23. The semiconductor device of claim 17 wherein the substrate comprises silicon.

24. The semiconductor device of claim 17 wherein the substrate comprises silicon with defective crystalline.

25. The semiconductor device of claim 17 wherein the memory device comprises a stack-type dynamic random access memory (DRAM).

26. The semiconductor device of claim 17 wherein the memory device comprises a trench-type dynamic random access memory (DRAM).

27. The semiconductor device of claim 17 wherein the memory device comprises a dynamic random access memory (DRAM), static random access memory (SRAM), magnetic RAM, or non-volatile memory.

28. The semiconductor device of claim 16 wherein the memory device comprises Electrically Programmable Memory (EPROM) or Electrically Erasable Programmable Memory (E2PROM).

29. The semiconductor device of claim 16 wherein the logic device comprises a metal-oxide semiconductor field-effect transistor (MOSFET), wherein the MOSFET comprises a channel in <100> crystalline direction.

30. The semiconductor device of claim 16 wherein the logic device comprises an electrically conductive gate electrode, wherein the electrically conductive gate electrode is selected from the group consisting of: metal, metal silicide, metal nitride, metal alloy, and a metal compound.

31. The semiconductor device of claim 16 wherein the logic device comprises an electrically conductive gate electrode, wherein the electrically conductive gate electrode comprises titanium nitride.

32. The semiconductor device of claim 16 wherein the logic device comprises an electrically conductive gate electrode, wherein the width of the electrically conductive gate electrode is less than 900 Angstroms.

33. The semiconductor device of claim 16 wherein the memory device comprises a gate electrode, wherein the gate electrode comprises metal silicide or polysilicon.

34. The semiconductor device of claim 16 wherein the memory device comprises a gate electrode, wherein the width of the gate electrode is less than 1300 Angstroms.

35. A method for semiconductor manufacturing, comprising:
providing a substrate;
forming a first gate dielectric with a high dielectric constant (high-k) material, wherein the first gate dielectric is for a logic device; and
forming a second gate dielectric with a non-high-k material, wherein the second gate dielectric is for a memory device.

36. The method of claim 35 wherein the high-k gate dielectric comprises tantalum pentoxide.

37. The method of claim 35 wherein the high-k gate dielectric comprises hafnium oxide.

38. The method of claim 35 wherein the high-k gate dielectric comprises aluminum oxide.

39. The method of claim 35 wherein the high-k gate dielectric is selected from the group consisting of: titanium oxide, barium strontium titanate, zirconium oxide, hafnium silicon oxide, zirconium silicon oxide, hafnium aluminum oxide, zirconium aluminum oxide, and strontium titanium oxide.

40. The method of claim 35 further comprising forming an insulating layer that comprises silicon nitride or silicon oxynitride under the first gate dielectric.
